(19) United States
(12) Patent Application Publication
(10) Pub. No.: US 2022/0208883 A1
(43) Pub. Date: Jun. 30, 2022

(54) DISPLAY DEVICE

(71) Applicant: LG DISPLAY CO., LTD., SEOUL (KR)

(72) Inventors: MoonSoo KIM, Paju-si (KR); Sungbai LEE, Paju-si (KR)

(73) Assignee: LG DISPLAY CO., LTD., SEOUL (KR)

(21) Appl. No.: 17/549,340

(22) Filed: Dec. 13, 2021

(30) Foreign Application Priority Data
Dec. 30, 2020 (KR) 10-2020-0188414

(51) Int. Cl. H01L 27/32; H01L 51/52

(52) U.S. Cl. CPC H01L 27/3218; H01L 51/5218; H01L 51/5234

(57) ABSTRACT

A display device includes a substrate provided with a display area for displaying an image by a plurality of subpixels, a driving transistor provided over the substrate, a first electrode provided in each of the plurality of subpixels over the driving transistor and comprised of a plurality of divided electrodes and a bridge electrode connecting the plurality of divided electrodes, a connection portion having one end connected to the driving transistor through a contact hole and another connected to the first electrode, a light emitting layer provided over the first electrode, and a second electrode provided over the light emitting layer, thereby reducing or minimizing a size of a light emission area that becomes a dark spot caused by unintended particles located therein.

### CROSS-REFERENCE TO RELATED APPLICATION

This application claims the benefit of and priority to Korean Patent Application No. 10-2020-0188414 filed on Dec. 30, 2020, which is hereby incorporated by reference in its entirety.

### BACKGROUND

### Field of the Disclosure

The present disclosure relates to a display device. Although the present disclosure is suitable for a wide scope of applications, it is particularly suitable for reducing or minimizing a size of a light emission area that becomes a dark spot in the display device.

### Description of the Background

A display device includes a first electrode, a light emitting layer, and a second electrode, which are sequentially deposited, and emits light through the light emitting layer when a voltage is applied to the first electrode and the second electrode. In this display device, unintended particles may be located on the first electrode during a manufacturing process, and in this case, a short-circuit may occur between the first electrode and the second electrode in the area where the unintended particles are located. For this reason, the display device has a problem in that all of subpixels in which unintended particles are located become dark spots so as not to emit light.

Recently, studies for a transparent display device in which a user may view objects or images positioned at the opposite side by transmitting the display device are actively ongoing.

The transparent display device includes a display area on which an image is displayed, and a non-display area, wherein the display area may include a transmissive area capable of transmitting external light, and a non-transmissive area. The transparent display device have high light transmittance in the display area through the transmissive area.

The transparent display device has a small sized light emission area due to the transmissive area as compared with a regular display device. Therefore, when all of subpixels become dark spots due to unintended particles, luminance deterioration can occur in the transparent display device more remarkably than the regular display device.

### SUMMARY

Accordingly, the present disclosure has been made in view of various technical problems including the above problems, and various aspects of the present disclosure provide a display device that may reduce or minimize a size of a light emission area that becomes a dark spot.

In addition to the technical benefits of the present disclosure as mentioned above, additional technical benefits and features of the present disclosure will be clearly understood by those skilled in the art from the following description of the present disclosure.

In accordance with an aspect of the present disclosure, the above and other technical benefits can be accomplished by the provision of a display device comprising a substrate provided with a display area for displaying an image by a plurality of subpixels, a driving transistor provided over the substrate, a first electrode provided in each of the plurality of subpixels over the driving transistor and comprised of a plurality of divided electrodes and a bridge electrode connecting the plurality of divided electrodes, a connection portion having one end connected to the driving transistor through a contact hole and another end connected to the first electrode, a light emitting layer provided over the first electrode, and a second electrode provided over the light emitting layer.

In accordance with another aspect of the present disclosure, the above and other technical benefits can be accomplished by the provision of a display device comprising a substrate provided with transmissive areas and a plurality of subpixels disposed between the transmissive areas, a first electrode provided in each of the plurality of subpixels over the substrate, including a plurality of divided electrodes and a bridge electrode disposed between two adjacent divided electrodes to connect the divided electrodes, a light emitting layer provided over the first electrode, and a second electrode disposed over the light emitting layer.

### BRIEF DESCRIPTION OF THE DRAWINGS

The above and other features and advantages of the present disclosure will be more clearly understood from the following detailed description taken in conjunction with the accompanying drawings, in which:

FIG. 1 is a perspective view illustrating a display device according to one aspect of the present disclosure;

FIG. 2 is a schematic plan view illustrating a display panel according to one aspect of the present disclosure;

FIG. 3 is a view illustrating an example of a pixel provided in a display panel;

FIG. 4 is a view illustrating a first electrode provided in the pixel shown in FIG. 3;

FIG. 5 is a cross-sectional view illustrating an example of line I-I′ of FIG. 4;

FIG. 6 is a cross-sectional view illustrating an example of line II-IF of FIG. 4;

FIG. 7 is a view illustrating an example that unintended particles are located in one of a plurality of divided electrodes;

FIG. 8 is a cross-sectional view illustrating an example of line of FIG. 7;

FIG. 9 is a view illustrating a modified example of a first electrode shown in FIG. 4;

FIG. 10 is a view illustrating another example of a pixel provided in a display panel;

FIG. 11 is a view illustrating a first electrode provided in the pixel shown in FIG. 10; and

FIG. 12 is a cross-sectional view illustrating an example of line IV-IV′ of FIG. 10.

### DETAILED DESCRIPTION

Advantages and features of the present disclosure, and implementation methods thereof will be clarified through following aspects described with reference to the accompanying drawings. The present disclosure may, however, be embodied in different forms and should not be construed as limited to the aspects set forth herein. Rather, these aspects are provided so that this disclosure will be thorough and complete, and will fully convey the scope of the present disclosure to those skilled in the art.

A shape, a size, a ratio, an angle, and a number disclosed in the drawings for describing aspects of the present disclosure are merely an example, and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted. In a case where ‘comprise’, ‘have’, and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when the position relationship is described as ‘upon˜’, ‘above˜’, ‘below˜’, and ‘next to˜’, one or more portions may be arranged between two other portions unless ‘just’ or ‘direct’ is used.

It will be understood that, although the terms “first”, “second”, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing elements of the present disclosure, the terms “first”, “second”, etc. may be used. These terms are intended to identify the corresponding elements from the other elements, and basis, order, or number of the corresponding elements are not limited by these terms. The expression that an element is “connected” or “coupled” to another element should be understood that the element may directly be connected or coupled to another element but may directly be connected or coupled to another element unless specially mentioned, or a third element may be interposed between the corresponding elements.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in co-dependent relationship.

Hereinafter, an example of a display device according to the present disclosure will be described More specifically with reference to the accompanying drawings. Wherever possible, the same reference numbers will be used throughout the drawings to refer to the same or like parts.

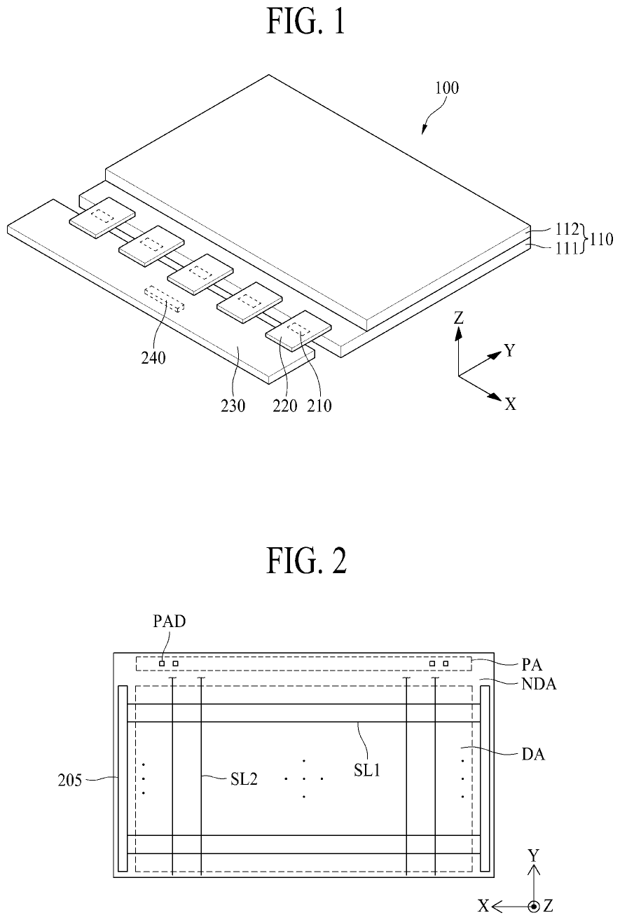

FIG. 1 is a perspective view illustrating a display device according to one aspect of the present disclosure.

Hereinafter, X axis indicates a line parallel with a scan line, Y axis indicates a line parallel with a data line, and Z axis indicates a height direction of a display device 100.

Although a description is described based on that the display device 100 according to one aspect of the present disclosure is embodied as an organic light emitting display device, the display device 100 may be embodied as a liquid crystal display device, a plasma display panel (PDP), a quantum dot light emitting display (QLED) or an electrophoresis display device (EDD).

Referring back to FIG. 1, the display device 100 according to one aspect of the present disclosure includes a display panel 110, a source drive integrated circuit (IC) 210, a flexible film 220, a circuit board 230, and a timing controller 240.

The display panel 110 may include a first substrate 111 and a second substrate 112, which face each other. The second substrate 112 may include an encapsulation substrate. The first substrate 111 may include one of a plastic film, a glass substrate, and a silicon wafer substrate formed using a semiconductor process. The second substrate 112 may include one of a plastic film, a glass substrate, and an encapsulation film. The first substrate 111 and the second substrate 112 may be made of a transparent material.

The scan driver may be provided in one side of the display area of the display panel 110, or the non-display area of both peripheral sides of the display panel 110 by a gate driver in panel (GIP) method. In another way, the scan driver may be manufactured in a driving chip, may be mounted on the flexible film, and may be attached to one peripheral side or both peripheral sides of the display area of the display panel 110 by a tape automated bonding (TAB) method.

When the source drive IC 210 is manufactured in a driving chip, the source drive IC 210 may be mounted on the flexible film 220 by a chip on film (COF) method or a chip on plastic (COP) method.

Pads, such as power pads and data pads, may be provided in the pad area PA of the display panel 110. Lines connecting the pads with the source drive IC 210 and lines connecting the pads with lines of the circuit board 230 may be provided in the flexible film 220. The flexible film 220 may be attached onto the pads using an anisotropic conducting film, so that the pads may be connected with the lines of the flexible film 220.

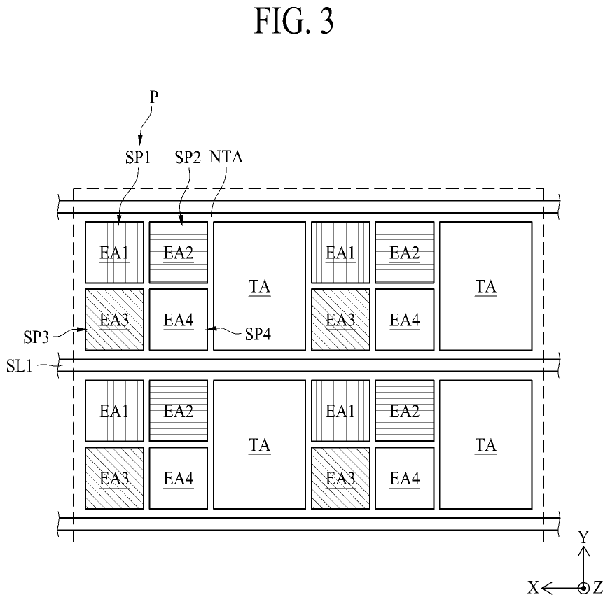

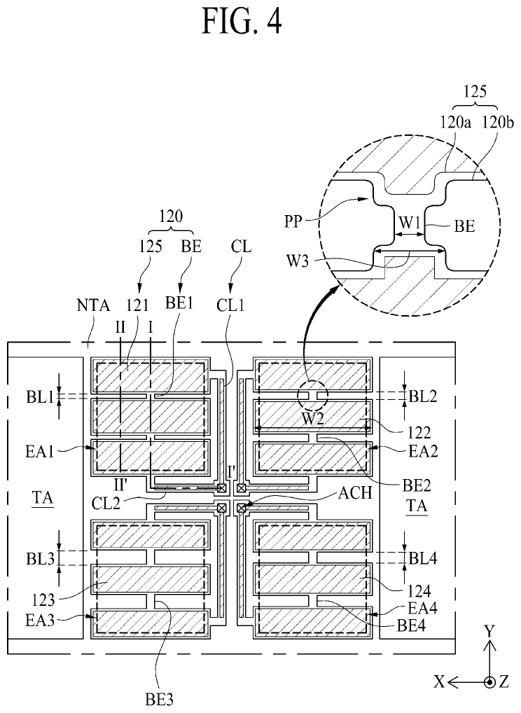

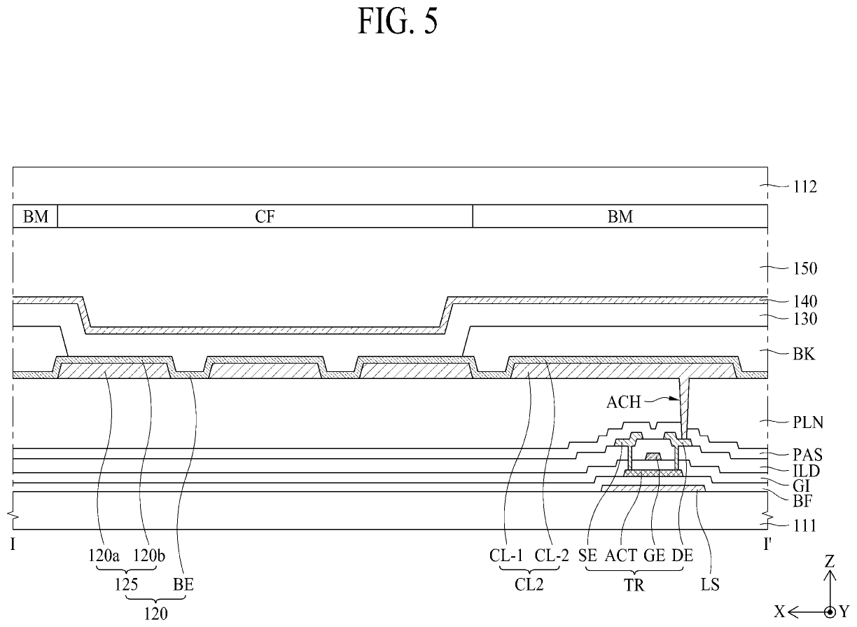

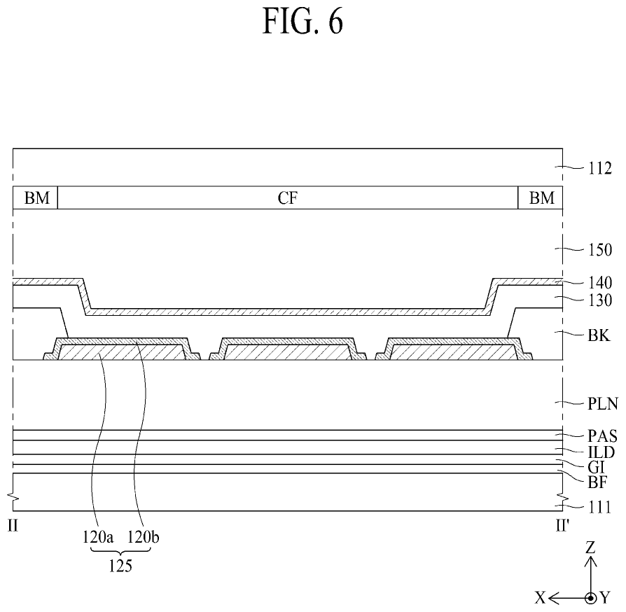

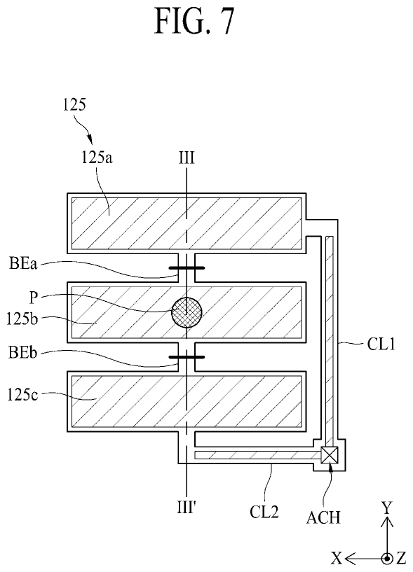

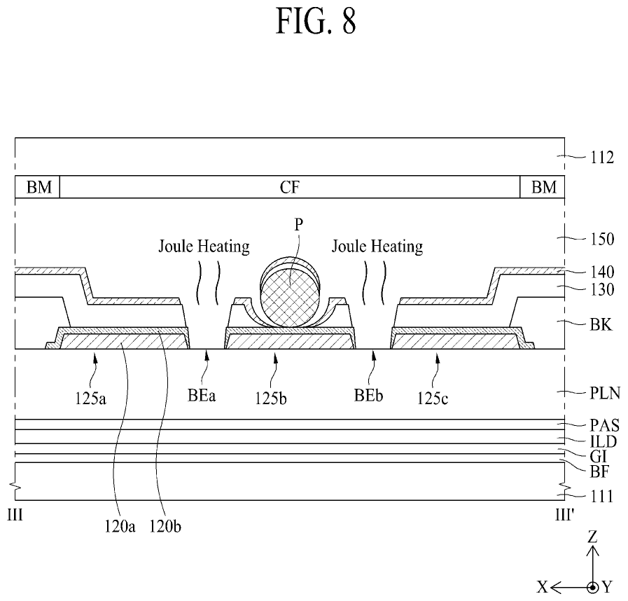

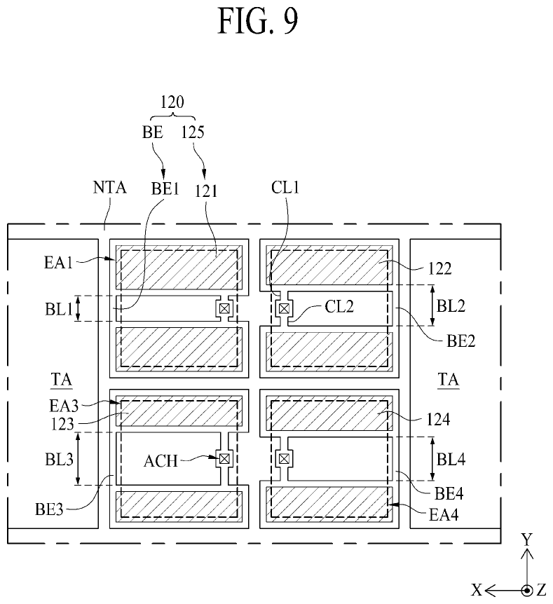

FIG. 2 is a schematic plan view illustrating a display panel according to one aspect of the present disclosure, FIG. 3 is a view illustrating an example of a pixel provided in a display panel, and FIG. 4 is a view illustrating a first electrode (functioning as an anode electrode) provided in the pixel shown in FIG. 3. FIG. 5 is a cross-sectional view illustrating an example of line I-I′ of FIG. 4, and FIG. 6 is a cross-sectional view illustrating an example of line II-IF of FIG. 4. FIG. 7 is a view illustrating an example that unintended particles are located in one of a plurality of divided electrodes, and FIG. 8 is a cross-sectional view illustrating an example of line of FIG. 7. FIG. 9 is a view illustrating a modified example of a first electrode shown in FIG. 4.

In the following descriptions, although the display panel 110 is embodied as a transparent display panel, the display panel 110 may be embodied as a regular display panel in which a transmissive area TA is not provided.

Referring back to FIG. 2 and FIG. 9, the first substrate 111 may include a display area DA provided with pixels P to display an image, and a non-display area NDA for not displaying an image.

The non-display area NDA may be provided with a pad area PA in which pads PAD are disposed, and at least one scan driver 205.

The scan driver 205 are connected to the scan lines SL and supplies scan signals to the scan lines SL. The scan driver 205 may be disposed in one side of the display area DA of the display panel 110, or the non-display area NDA of both peripheral sides of the display panel 110 by a gate driver in panel (GIP) method. For example, as shown in FIG. 2, the scan driver 205 may be provided in both side of the display area DA of the display panel 110, but these scan drivers are not limited thereto. The scan driver 205 may be provided only in one side of the display area DA of the display panel 110.

The display area DA, as shown in FIG. 3, includes a transmissive area TA and a non-transmissive area NTA. The transmissive area TA is an area through which most of externally incident light passes, and the non-transmissive area NTA is an area through which most of externally incident light does not transmit. For example, the transmissive area TA may be an area where light transmittance is greater than α%, for example, about 90%, and the non-transmissive area NTA may be an area where light transmittance is smaller than β%, for example, about 50%. At this time, α is greater than β. A user may view an object or background arranged over a rear surface of the display panel 110 due to the transmissive area TA.

The non-transmissive area NTA may include a plurality of pixels P, and a plurality of first and second signal lines SL1 and SL2 for supplying signals to the plurality of pixels P, respectively.

The plurality of first signal lines SL1 may be extended in a first direction (e.g., X-axis direction). The plurality of first signal lines SL1 may cross the plurality of second signal lines SL2. Each of the plurality of first signal lines SL1 may include at least one scan line.

Hereinafter, when the first signal line SL1 includes a plurality of lines, one first signal line SL1 may refer to a signal line group including a plurality of lines. For example, one first signal line SL1 may refer to a signal line group including two scan lines.

The plurality of second signal lines SL2 may be extended in a second direction (e.g., Y-axis direction). Each of the plurality of second signal lines SL2 may include at least one of at least one data line, a reference line, a pixel power line, or a common power line.

Hereinafter, when the second signal line SL2 includes a plurality of lines, one second signal line SL2 may refer to a signal line group including a plurality of lines. For example, one second signal line SL2 may refer to a signal line group including two data lines, a reference line, a pixel power line and a common power line.

A transmissive area TA may be disposed between adjacent first signal lines SL1. In addition, the transmissive area TA may be disposed between adjacent second signal lines SL2. As a result, the transmissive area TA may be surrounded by two first signal lines SL1 and two second signal lines SL2.

Pixels P may be provided to overlap at least one of the first signal line SL1 and the second signal line SL2, thereby emitting predetermined light to display an image. An emission area EA may correspond to an area, from which light is emitted, in the pixel P.

Each of the pixels P may include at least one of a first subpixel P1, a second subpixel P2, a third subpixel P3 and a fourth subpixel P4. The first subpixel P1 may include a first emission area EA1 emitting light of a red color. The second subpixel P2 may include a second emission area EA2 emitting light of a green color. The third subpixel P3 may include a third emission area EA3 emitting light of a blue color. The fourth subpixel P4 may include a fourth emission area EA4 emitting light of a white color. However, the emission areas are not limited to this example. Each of the pixels P may further include a subpixel emitting light of a color other than red, green, blue and white. Also, the arrangement order of the subpixels P1, P2, P3 and P4 may be changed in various ways.

Hereinafter, for convenience of description, the description will be given based on that a first subpixel P1 is a red subpixel emitting red light, a second subpixel P2 is a green subpixel emitting green light, a third subpixel P3 is a blue subpixel emitting blue light, and a fourth subpixel P4 is a white subpixel emitting white light.

Each of the plurality of pixels P may be provided in a non-transmissive area NTA disposed between the transmissive areas TA. The plurality of pixels P may be disposed to be adjacent to each other in the non-transmissive area NTA in the second direction (e.g., Y-axis direction). For example, two of the plurality of pixels P may be disposed to be adjacent to each other in the non-transmissive area NTA with the first signal line SL1 interposed therebetween.

Each of the plurality of pixels P may include a first subpixel SP1, a second subpixel SP2 and a third subpixel SP3, and may further include a fourth subpixel SP4 in accordance with one aspect. Each of the plurality of pixels P may include a first subpixel SP1, a second subpixel SP2, a third subpixel SP3 and a fourth subpixel SP4, which are disposed in a grid structure. For example, each of the plurality of pixels P may include a first subpixel SP1, a second subpixel SP2, a third subpixel SP3 and a fourth subpixel SP4, which are disposed around a middle area. In this case, the middle area may indicate an area that includes a middle portion of each pixel P and has a predetermined size.

More specifically, the first and second subpixels SP1 and SP2 may be disposed to be adjacent to each other based on the middle area of the pixel P in the first direction (e.g., X-axis direction), and the third and fourth subpixels SP3 and SP4 may be disposed to be adjacent to each other based on the middle area of the pixel P in the first direction (e.g., X-axis direction). One of the first and second subpixels SP1 and SP2 may be disposed to be adjacent to one of the third and fourth subpixels SP3 and SP4 in the second direction (e.g., Y-axis direction).

Each of the first subpixel SP1, the second subpixel SP2, the third subpixel SP3 and the fourth subpixel SP4, which are disposed as described above, may include a circuit element including a capacitor, a thin film transistor and the like, a plurality of signal lines for supplying a signal to the circuit element, and a light emitting element. The thin film transistor may include a switching transistor, a sensing transistor and a driving transistor TR.

In the display panel 110, the plurality of signal lines as well as the first subpixel SP1, the second subpixel SP2, the third subpixel SP3 and the fourth subpixel SP4 should be disposed in the non-transmissive area NTA except the transmissive area TA. Therefore, the first subpixel SP1, the second subpixel SP2, the third subpixel SP3 and the fourth subpixel SP4 may overlap at least one of the first signal line SL1 or the second signal line SL2.

Although the first subpixel SP1, the second subpixel SP2, the third subpixel SP3 and the fourth subpixel SP4 overlap at least a portion of the second signal line SL2 but do not overlap the first signal line SL1 as shown, the aspect of the present disclosure is not limited thereto. In another aspect, at least a portion of the first subpixel SP1, the second subpixel SP2, the third subpixel SP3 and the fourth subpixel SP4 may overlap the first signal line SL1.

The plurality of signal lines may include a first signal line SL1 extended in a first direction (e.g., X-axis direction) and a second signal line SL2 extended in a second direction (e.g., Y-axis direction) as described above.

The first signal line SL1 may include a scan line. The scan line may supply a scan signal to the subpixels SP1, SP2, SP3 and SP4 of the pixel P.

The second signal line SL2 may include at least one of at least one data line, a reference line, a pixel power line, or a common power line.

The reference line may supply a reference voltage (or an initialization voltage or a sensing voltage) to the driving transistor TR of each of the subpixels SP1, SP2, SP3 and SP4 provided in the display area DA.

Each of the at least one data line may supply a data voltage to at least one of the subpixels SP1, SP2, SP3 and SP4 provided in the display area DA. For example, the first data line may supply a first data voltage to the driving transistor TR of each of the first and third subpixels SP1 and SP3, and the second data line may supply a second data voltage to the driving transistor TR of each of the second and fourth subpixels SP2 and SP4.

The pixel power line may supply a first power source to the first electrode 120 of each of the subpixels SP1, SP2, SP3 and SP4. The common power line may supply a second power source to the second electrode 140 of each of the subpixels SP1, SP2, SP3 and SP4.

The switching transistor is switched in accordance with the scan signal supplied to the scan line to supply the data voltage supplied from the data line to the driving transistor TR.

The sensing transistor serves to sense a deviation in a threshold voltage of the driving transistor TR, which causes deterioration of image quality.

The driving transistor TR is switched in accordance with the data voltage supplied from the switching thin film transistor to generate a data current from a power source supplied from the pixel power line and supply the data current to the first electrode 120 of the subpixel. The driving transistor TR is provided for each of the subpixels SP1, SP2, SP3 and SP4, and includes an active layer ACT, a gate electrode GE, a source electrode SE and a drain electrode DE.

The capacitor serves to maintain the data voltage supplied to the driving transistor TR for one frame. The capacitor may include a first capacitor electrode and a second capacitor electrode, but is not limited thereto. In another aspect, the capacitor may include three capacitor electrodes.

Referring to FIG. 5 and FIG. 6, an active layer ACT may be provided over a first substrate 111. The active layer ACT may be formed of a silicon-based semiconductor material or an oxide-based semiconductor material.

A light shielding layer LS for shielding external light incident on the active layer ACT may be provided between the active layer ACT and the first substrate 111. The light-shielding layer LS may be formed of a material having conductivity, and may be formed of a single layer or multi-layer made of one of molybdenum (Mo), aluminum (Al), chromium (Cr), gold (Au), titanium (Ti), nickel (Ni), neodymium (Nd) and copper (Cu), or their alloy. In this case, a buffer layer BF may be provided between the light shielding layer LS and the active layer ACT.

A gate insulating layer GI may be provided over the active layer ACT. The gate insulating layer GI may be formed of an inorganic film, for example, a silicon oxide film (SiOX), a silicon nitride film (SiNx), or a multi-film of SiOx and SiNx.

A gate electrode GE may be provided over the gate insulating layer GI. The gate electrode GE may be formed of a single layer or multi-layer made of any one of molybdenum (Mo), aluminum (Al), chromium (Cr), gold (Au), titanium (Ti), nickel (Ni), neodymium (Nd) and copper (Cu), or their alloy.

An interlayer dielectric layer ILD may be provided over the gate electrode GE. The interlayer dielectric layer ILD may be formed of an inorganic film, for example, a silicon oxide film (SiOX), a silicon nitride film (SiNx), or a multi-film of SiOx and SiNx.

The source electrode SE and the drain electrode DE may be provided over the interlayer dielectric layer ILD. The source electrode SE and the drain electrode DE may be connected to the active layer ACT through a contact hole that passes through the gate insulating layer GI and the interlayer dielectric layer ILD.

The source electrode SE and the drain electrode DE may be formed of a single layer or multi-layer made of one of molybdenum (Mo), aluminum (Al), chromium (Cr), gold (Au), titanium (Ti), nickel (Ni), neodymium (Nd) and copper (Cu), or their alloy.

In addition, each of the plurality of signal lines, for example, the scan line, the data lines, reference line, pixel power line and common power line may be disposed on the same layer as any one of the light-shielding layer LS, the gate electrode GE, the source electrode SE and the drain electrode DE.

A passivation layer PAS for protecting the driving transistor TR may be provided over the source electrode SE and the drain electrode DE. A planarization layer PLN may be provided over the passivation layer PAS to planarize a step difference (or a step coverage) due to the formation of the driving transistor TR.

Light emitting elements includes a first electrode 120 (function an anode electrode), a light emitting layer 130 and a second electrode 140 (functioning as a cathode electrode), and a bank BK are provided over the planarization layer PLN.

The first electrode 120 may be provided for each of the subpixels SP1, SP2, SP3 and SP4. More specifically, one first electrode 120 may be provided in the first subpixel SP1, another first electrode 120 may be provided in the second subpixel SP2, still another first electrode 120 may be provided in the third subpixel SP3, and further still another first electrode 120 may be provided in the fourth subpixel SP4. The first electrode 120 is not provided in the transmissive area TA.

The first electrode 120 provided in each of the plurality of subpixels SP1, SP2, SP3 and SP4 may include a plurality of divided electrodes 125 and at least one bridge electrode BE.

The plurality of divided electrodes 125 may include two or more, and may be disposed to be spaced apart from each other in the first direction (e.g., X-axis direction) or the second direction (e.g., Y-axis direction). For example, the plurality of divided electrodes 125 may include three as shown in FIGS. 4 to 6 and may be disposed to be spaced apart from one another in the second direction (e.g., Y-axis direction), but are not limited thereto. The plurality of divided electrodes 125 may include two, or may include four or more. Hereinafter, for convenience of description, the plurality of divided electrodes 125 include three.

Each of the plurality of divided electrodes 125 may include a first electrode layer 120a, and a second electrode layer 120b disposed over the first electrode layer 120a, as shown in FIGS. 5 and 6.

The first electrode layer 120a may be made of a first material. The first material may include a metal material having high reflectance. For example, the first material may be, but is not limited to, molybdenum (Mo), molybdenum-titanium (MoTi) alloy, or copper (Cu). The first material may be a material having higher reflectance and lower resistance than a second material that will be described later. Alternatively, the first material may be a material having a melting point higher than that of the second material.

The second electrode layer 120b may be made of a second material. The second material may include a transparent material. For example, the second material may be ITO, but is not limited thereto. The second material may be a material having higher resistance than the first material. Alternatively, the second material may be a material having a melting point higher than or equal to a predetermined temperature and lower than that of the first material.

The bridge electrode BE may be disposed between the plurality of divided electrodes 125 to connect the plurality of divided electrodes 125 with each other. More specifically, one bridge electrode BE may be disposed between two adjacent divided electrodes 125. At this time, the bridge electrodes BE may be provided in the same layer as the second electrode layer 120b of the divided electrodes 125.

In this case, one end of the bridge electrode BE may be connected to any one second electrode layer 120b of two divided electrodes 125, and the other end thereof may be connected to the other second electrode layer 120b of the two divided electrodes 125.

A first width W1 of a side of the bridge electrode BE, which is in contact with the divided electrodes 125, may be smaller than a second width W2 of the divided electrodes 125. Since the bridge electrode BE is provided to be thinner than the divided electrodes 125, resistance of the bridge electrode BE may be greater than that of the divided electrodes 125.

Meanwhile, the divided electrodes 125 may be provided with a protrusion portion PP protruded toward the bridge electrode BE at a third width W3 narrower than a second width W2 of a side, which is in contact with the bridge electrode BE, for example, a long side. As a result, resistance may gradually be increased as a current flows from the divided electrode 125 to the bridge electrode BE, and may gradually be reduced as the current flows from the bridge electrode BE to the divided electrode 125.

As described above, the first electrode 120, which includes the plurality of divided electrodes 125 and the bridge electrode BE, may be connected with the driving transistor TR through a connection portion CL. One end of the connection portion CL may be connected with the driving transistor TR through a contact hole ACH, and the other end thereof may be connected with the first electrode 120.

In the display panel 110 according to one aspect of the present disclosure, one first electrode 120 may be connected to the driving transistor TR through two connection portions CL. More specifically, the connection portion CL may include a first connection portion CL1 and a second connection portion CL2, and each of the first connection portion CL1 and the second connection portion CL2 may be connected to the driving transistor TR through a contact hole ACH that passes through the planarization layer PLN and the passivation layer PAS.

In one aspect, the contact hole ACH may be provided among the subpixels SP1, SP2, SP3 and SP4 as shown in FIG. 4. Each of the first connection portion CL1 and the second connection portion CL2 may be provided among the subpixels SP1, SP2, SP3 and SP4. The first connection portion CL1 may be provided between the subpixels adjacent to each other in the first direction, and the second connection portion CL2 may be provided between the subpixels adjacent to each other in the second direction.

In another aspect, the contact hole ACH may be provided between the divided electrodes 125 provided in each of the subpixels SP1, SP2, SP3 and SP4, as shown in FIG. 9. Each of the first connection portion CL1 and the second connection portion CL2 may be provided between the divided electrodes 125.

One end of the first connection portion CL1 may be connected with a source electrode SE or a drain electrode of the driving transistor TR through the contact hole ACH. The other end of the first connection portion CL1 may be connected with any one of the plurality of divided electrodes 125 provided in the first electrode 120. At this time, the first connection portion CL1 may be connected to the divided electrode, which is disposed at the outermost portion on a first side, of the plurality of divided electrodes 125.

One end of the second connection portion CL2 may be connected with the source electrode SE or the drain electrode of the driving transistor TR through the contact hole ACH. In addition, the other end of the second connection portion CL2 may be connected to the other one of the plurality of divided electrodes 125 provided in the first electrode 120. At this time, the second connection portion CL2 may be connected to the divided electrode, which is disposed at the outermost portion on a second side, of the plurality of divided electrodes 125.

For example, three divided electrodes 125 may be disposed in a line in the second direction (e.g., Y-axis direction) as shown in FIG. 4. The bridge electrode BE may be disposed between adjacent divided electrodes 125. Therefore, the three divided electrodes 125 may electrically be connected to one another through the bridge electrode BE.

One end of the first connection portion CL1 may be connected with the source electrode SE or the drain electrode DE of the driving transistor TR through the contact hole ACH, and the other end thereof may be connected with one of the three divided electrodes 125. The first connection portion CL1 may be connected to the divided electrode, which is disposed at the outermost portion on a first side, of the three divided electrodes 125 disposed in a line.

One end of the second connection portion CL2 may be connected to the source electrode SE or the drain electrode DE of the driving transistor TR through the contact hole ACH, and the other end thereof may be connected with the other one of the three divided electrodes 125. The first connection portion CL1 may be connected to the divided electrode, which is disposed at the outermost portion on a second side, of the three divided electrodes 125 disposed in a line.

In the first electrode 120 comprised of three divided electrodes 125, one divided electrode disposed at the outmost portion on the first side may be connected with the driving transistor TR through the first connection portion CL1, and another divided electrode disposed at the outermost portion on the second side may be connected with the driving transistor TR through the second connection portion CL2.

As a result, the three divided electrodes 125 may be connected with the driving transistor TR through the first connection portion CL1, and may be connected with the driving transistor TR through the second connection portion CL2.

The first and second connection portions CL1 and CL2 described as above may be formed as a double layer as shown in FIG. 5. More specifically, the first connection portion CL1 and the second connection portion CL2 may include a first layer CL-1 and a second layer CL-2. The first layer CL-1 may be provided in the same layer as the first electrode layer 120a of the divided electrode 125, and may be spaced apart from the first electrode layer 120a of the divided electrode 125. The second layer CL-2 may be provided in the same layer as the second electrode layer 120b of the divided electrode 125, and may be extended from the second electrode layer 120b of the divided electrode 125.

The display panel 110 according to one aspect of the present disclosure is characterized in that the first electrode 120 may include a plurality of divided electrodes 125 and at least one bridge electrode BE is connected with the driving transistor TR through two connection portions CL1 and CL2. Therefore, in the display panel 110 according to one aspect of the present disclosure, even though unintended particles are located in a portion of the plurality of divided electrodes 125, only the corresponding divided electrode becomes a dark spot, and the other divided electrodes may normally operate.

More specifically, in the display panel 110 according to one aspect of the present disclosure, as shown in FIG. 7, unintended particles P may be located in one of the plurality of divided electrodes 125. For example, one first electrode 120 may include three divided electrodes 125a, 125b and 125c and two bridge electrodes BEa and BEb. When unintended particles P are located in one 125b of the three divided electrodes 125a, 125b and 125c, the divided electrode 125b in which the unintended particles P are located may generate a short with the second electrode 140. Therefore, the organic light emitting layer 130 provided over the divided electrode 125b in which the unintended particles P are located does not emit light.

In the display panel 110 according to one aspect of the present disclosure, the divided electrodes 125b in which the unintended particles P are located may be disconnected from the other divided electrodes 125a and 125c, whereby the organic light emitting layer 130 provided over the other divided electrodes 125a and 125c may emit light.

The bridge electrodes BEa and BEb connected to the divided electrode 125b in which the unintended particles P are located may be disconnected by Joule heating. When the divided electrode 125b in which the unintended particles P are located causes a short-circuit with the second electrode 140, a current may be concentrated on the divided electrode 125b that causes a short-circuit with the second electrode 140. As a result, the current may be concentrated on the bridge electrodes BEa and BEb connected with the divided electrode 125b in which the unintended particles P are located.

The bridge electrodes BEa and BEb may be extended from the second electrode layer 120b made of the second material as described above. Since resistance of the second material is higher than that of the first material, high heat may be generated when the current is concentrated on the bridge electrodes BEa and BEb and the divided electrode 125b in which the unintended particles P are located.

Furthermore, the bridge electrodes BEa and BEb may be provided to have a width very narrower than that of the divided electrodes 125a, 125b and 125c, thereby having resistance higher than that of the divided electrodes 125a, 125b and 125c. Therefore, the bridge electrodes BEa and BEb generate heat higher than that of the divided electrodes 125a, 125b and 125c, and eventually rise to a temperature higher than the melting point of the second material. As a result, the bridge electrodes BEa and BEb may be melted and disconnected as shown in FIG. 8.

When the bridge electrodes BEa and BEb connected with the divided electrode 125b in which the unintended particles P are located, the divided electrodes 125a and 125c in which the unintended particles P are not located are electrically separated from the divided electrode 125b in which the unintended particles P are located. Therefore, the divided electrodes 125a and 125c in which the unintended particles P are not located cannot receive a signal supplied by the driving transistor TR through the divided electrode 125b in which the unintended particles P are located.

However, in the display panel 110 according to one aspect of the present disclosure, since the first electrode 120 is connected with the driving transistor TR through the two connection portions CL1 and CL2, even though the bridge electrodes BEa and BEb connected with the divided electrode 125b in which the unintended particles P are located are disconnected, the signal supplied by the driving transistor TR may stably be supplied to the other divided electrodes 125a and 125c.

For example, when the first electrode 120 is connected with the driving transistor TR through one connection portion CL1 and the bridge electrodes BEa and BEb connected with the divided electrode 125b in which the unintended particles P are located are disconnected, some divided electrode 125c may electrically be disconnected from the driving transistor TR. In this case, the divided electrode 125c electrically disconnected from the driving transistor TR may become a dark spot even though the unintended particles P are not located therein.

On the other hand, in the display panel 110 according to one aspect of the present disclosure, the first electrode 120 is connected to the driving transistor TR through the two connection portions CL1 and CL2. In the display panel 110 according to one aspect of the present disclosure, even though the bridge electrodes BEa and BEb are disconnected, one divided electrode 125a may be connected with the driving transistor TR through the first connection portion CL1, and the other divided electrode 125c may be connected with the driving transistor TR through the second connection portion CL2.

That is, in the display panel 110 according to one aspect of the present disclosure, the area provided with the divided electrode 125b in which the unintended particles P are located among the plurality of divided electrodes 125a, 125b and 125c becomes a dark spot, and light may normally be emitted in the area provided with the other divided electrodes 125a and 125c. The display panel 110 according to one aspect of the present disclosure may reduce or minimize the size of the light emission area that becomes a dark spot when the unintended particles P are located.

Meanwhile, the display panel 110 according to one aspect of the present disclosure may be designed such that the bridge electrodes BE provided in the first to fourth subpixels SP1, SP2, SP3 and SP4 have their respective lengths different from one another.

More specifically, the first electrode 120 provided in the first subpixel SP1 may include a plurality of first divided electrodes 121 and at least one first bridge electrode BE1. The first electrode 120 provided in the second subpixel SP2 may include a plurality of second divided electrodes 122 and at least one second bridge electrode BE2. The first electrode 120 provided in the third subpixel SP3 may include a plurality of third divided electrodes 123 and at least one third bridge electrode BE3. The first electrode 120 provided in the fourth subpixel SP4 may include a plurality of fourth divided electrodes 124 and at least one fourth bridge electrode BE4.

In the display panel 110 according to one aspect of the present disclosure, the first to fourth bridge electrodes BE1, BE2, BE3 and BE4 may be provided to have their respective lengths different from one another in consideration of the magnitude of the current supplied from the driving transistor TR.

A current required for each of the first to fourth subpixels SP1, SP2, SP3 and SP4 may be different depending on a color of light emitted from each of the first to fourth subpixels SP1, SP2, SP3 and SP4. A size of the driving transistor TR provided in each of the first to fourth subpixels SP1, SP2, SP3 and SP4 may be determined in consideration of the required current. For example, the current required for the first subpixel SP1 emitting red light among the first to fourth subpixels SP1, SP2, SP3 and SP4 may be the largest. In this case, the driving transistor TR connected with the first electrode 120 of the first subpixel SP1 may be larger than the driving transistor TR of the second to fourth subpixels SP2, SP3 and SP4. For another example, the current required for the third subpixel SP3 that emits blue light among the first to fourth subpixels SP1, SP2, SP3 and SP4 may be the smallest. In this case, the driving transistor TR connected with the first electrode 120 of the third subpixel SP3 may be provided to be smaller than the driving transistor TR of the first, second and fourth subpixels SP1, SP2 and SP4.

The first to fourth bridge electrodes BE1, BE2, BE3 and BE4 respectively provided in the first to fourth subpixels SP1, SP2, SP3 and SP4 may vary in resistance depending on the sizes of the driving transistors TR. When the size of the driving transistor TR is large, the current supplied from the driving transistor TR is large, whereby resistance of the bridge electrodes BE1, BE2, BE3 and BE4 may be large. On the other hand, when the size of the driving transistor TR is small, the current supplied from the driving transistor TR is small, whereby resistance of the bridge electrodes BE1, BE2, BE3 and BE4 may be small.

In the display panel 110 according to one aspect of the present disclosure, the length of the bridge electrodes BE1, BE2, BE3 and BE4 may be adjusted to adjust resistance of the current applied from the driving transistor TR to the bridge electrodes BE1, BE2, BE3 and BE4. Therefore, in the display panel 110 according to one aspect of the present disclosure, the first to fourth bridge electrodes BE1, BE2, BE3 and BE4 may have similar resistance.

For example, the driving transistor TR connected with the first electrode 120 of the first subpixel SP1 may be the largest, the driving transistor TR connected with the first electrode 120 of the second subpixel SP2 may be the second largest, the driving transistor TR connected with the first electrode 120 of the fourth subpixel SP4 may be the third largest, and the driving transistor TR connected with the first electrode 120 of the third subpixel SP3 may be the smallest. For example, the driving transistor TR connected with the first electrode 120 of the red subpixel SP1 may be the largest, the driving transistor TR connected with the first electrode 120 of the green subpixel SP2 may be the second largest, the driving transistor TR connected with the first electrode 120 of the white subpixel SP4 may be the third largest, and the driving transistor TR connected with the first electrode 120 of the blue subpixel SP3 may be the smallest.

In this case, a length BL1 of the first bridge electrode BE1 provided in the first subpixel SP1 may be shorter than a length BL2 of the second bridge electrode BE2 provided in the second subpixel SP2. The current applied to the first bridge electrode BE1 provided in the first subpixel SP1 may be greater than the current applied to the second bridge electrode BE2 provided in the second subpixel SP2. Therefore, the length BL1 of the first bridge electrode BE1 is shorter than the length BL2 of the second bridge electrode BE2, whereby a resistance difference between the first bridge electrode BE1 and the second bridge electrode BE2 may be reduced.

In addition, a length BL2 of the second bridge electrode BE2 provided in the second subpixel SP2 may be shorter than a length BL4 of the fourth bridge electrode BE4 provided in the fourth subpixel SP4. The current applied to the second bridge electrode BE2 provided in the second subpixel SP2 may be greater than the current applied to the fourth bridge electrode BE4 provided in the fourth subpixel SP4. Therefore, the length BL2 of the second bridge electrode BE2 is shorter than the length BL4 of the fourth bridge electrode BE4, whereby a resistance difference between the second bridge electrode BE2 and the fourth bridge electrode BE4 may be reduced.

A length BL4 of the fourth bridge electrode BE4 provided in the fourth subpixel SP4 may be shorter than a length BL3 of the third bridge electrode BE3 provided in the third subpixel SP3. The current applied to the fourth bridge electrode BE4 provided in the fourth subpixel SP4 may be greater than the current applied to the third bridge electrode BE3 provided in the third subpixel SP3. Therefore, the length BL4 of the fourth bridge electrode BE4 is shorter than the length BL3 of the third bridge electrode BE3, so that a resistance difference between the third bridge electrode BE3 and the fourth bridge electrode BE4 may be reduced.

As a result, the length BL1 of the first bridge electrode BE1 of the first subpixel SP1 may be the shortest, the length BL2 of the second bridge electrode BE2 of the second subpixel SP2 may be the second shortest, the length BL4 of the fourth bridge electrode BE4 of the fourth subpixel SP4 may be the third shortest, and the length BL3 of the third bridge electrode BE3 of the third subpixel SP3 may be the longest. For example, the length BL1 of the first bridge electrode BE1 of the red subpixel SP1 may be the shortest, the length BL2 of the second bridge electrode BE2 of the green subpixel SP2 may be the second shortest, the length BL4 of the fourth bridge electrode BE4 of the white subpixel SP4 may be the third shortest, and the length BL3 of the third bridge electrode BE3 of the blue subpixel SP3 may be the longest.

In the display panel 110 according to one aspect of the present disclosure as described above, when the current applied from the driving transistor TR is small, the length of the bridge electrode BE connected with the corresponding driving transistor TR may be increased, whereby resistance of the bridge electrode BE may be increased. Therefore, the display panel 110 according to one aspect of the present disclosure may make sure of disconnection of the bridge electrode BE when unintended particles are located on the divided electrode 125.

Meanwhile, in the display panel 110 according to one aspect of the present disclosure, the lengths of the bridge electrodes BE1, BE2, BE3 and BE4 are different from one another in each of the subpixels SP1, SP2, SP3 and SP4, whereby the sizes or the number of the divided electrodes 121, 122, 123 and 124 may be different from one another.

In one aspect, the divided electrodes 121, 122, 123 and 124 respectively provided in the subpixels SP1, SP2, SP3 and SP4 may be different from one another in width as shown in FIG. 4. More specifically, the divided electrodes 121, 122, 123 and 124 respectively provided in the subpixels SP1, SP2, SP3 and SP4 may have different widths in sides perpendicular to sides that are in contact with the bridge electrode BE1, BE2, BE3 and BE4, for example, short sides.

For example, the length BL1 of the first bridge electrode BE1 provided in the first subpixel SP1 may be longer than the length BL3 of the third bridge electrode BE3 provided in the third subpixel SP3. In this case, the first divided electrode 121 provided in the first subpixel SP1 may be wider than the third divided electrode 123 provided in the third subpixel SP3 in the width in the short side.

In another aspect, the divided electrodes 121, 122, 123 and 124 respectively provided in the subpixels SP1, SP2, SP3 and SP4 may be different from one another in number. For example, the length BL1 of the first bridge electrode BE1 provided in the first subpixel SP1 may be longer than the length BL3 of the third bridge electrode BE3 provided in the third subpixel SP3. In this case, the number of the first divided electrodes 121 provided in the first subpixel SP1 may be more than the number of the third divided electrodes 123 provided in the third subpixel SP3.

A bank BK may be provided over the planarization layer PLN. In addition, the bank BK may be provided between the first electrodes 120 provided in each of the first to fourth subpixels SP1, SP2, SP3 and SP4. The bank BK may be provided over the first connection portion CL1, the second connection portion CL2 and the contact hole ACH. At this time, the bank BK may be provided to cover or at least partially cover edges of each of first electrodes 120 and expose a portion of each of first electrodes 120. Therefore, the bank BK may prevent light emission efficiency from being deteriorated due to a current concentrated on ends of each of first electrodes 120.

Meanwhile, the bank BK may define the light emission areas EA1, EA2, EA3 and EA4 of each of the subpixels SP1, SP2, SP3 and SP4. The light emission areas EA1, EA2, EA3 and E4 of each of the subpixels SP1, SP2, SP3 and SP4 indicate areas in which the first electrode 120, the organic light emitting layer 130 and the second electrode 140 are sequentially deposited so that holes from the first electrode 120 and electrons from the second electrode 140 are combined with each other in the organic light emitting layer 130 to emit light. In this case, the area in which the bank BK is provided does not emit light, and thus becomes a non-light emission area, and the areas in which the bank BK is not provided and the first electrodes 120 are exposed may be the light emission areas EA1, EA2, EA3 and EA4.

The bank BK may be formed of an organic film such as an acrylic resin, an epoxy resin, a phenolic resin, a polyamide resin and a polyimide resin.

The organic light emitting layer 130 may be provided over the first electrode 120. The organic light emitting layer 130 may include a hole transporting layer, a light emitting layer and an electron transporting layer. In this case, when a voltage is applied to the first electrode 120 and the second electrode 140, holes and electrons move to the light emitting layer through the hole transport layer and the electron transport layer, respectively and are combined with each other in the light emitting layer to emit light.

In one aspect, the organic light emitting layer 130 may be a common layer commonly provided in the subpixels SP1, SP2, SP3 and SP4. In this case, the light emitting layer may be a white light emitting layer for emitting white light.

In another aspect, in the organic light emitting layer 130, a light emitting layer may be provided for each of the subpixels SP1, SP2, SP3 and SP4. For example, a red light emitting layer for emitting red light may be provided in the first subpixel SP1, a green light emitting layer for emitting green light may be provided in the second subpixel SP2, a blue light emitting layer for emitting blue light may be provided in the third subpixel SP3, and a white light emitting layer for emitting white light may be provided in the fourth subpixel SP4. In this case, the light emitting layer of the organic light emitting layer 130 is not provided in the transmissive area TA.

The second electrode 140 may be provided over the organic light emitting layer 130 and the bank BK. The second electrode 140 may also be provided in the transmissive area TA as well as the non-transmissive area NTA that includes a light emission area EA, but is not limited thereto. The second electrode 140 may be provided only in the non-transmissive area NTA that includes the light emission areas EA1, EA2, EA3 and EA4, and may not be provided in the transmissive area TA to improve transmittance.

The second electrode 140 may be a common layer that is commonly provided in the subpixels SP1, SP2, SP3 and SP4 to apply the same voltage. The cathode electrode 140 may be formed of a conductive material capable of transmitting light. For example, the cathode electrode 140 may be formed of a low resistance metal material such as silver (Ag) and an alloy of magnesium (Mg) and silver (Ag). The second electrode 140 may be a cathode electrode.

An encapsulation layer 150 may be provided over the light emitting elements. The encapsulation layer 150 may be provided over the second electrode 140 to overlay the second electrode 140. The encapsulation layer 150 serves to prevent oxygen or moisture from being permeated into the organic light emitting layer 130 and the second electrode 140. To this end, the encapsulation layer 150 may include at least one inorganic film and at least one organic film.

Although not shown in FIG. 5 and FIG. 6, a capping layer may further be provided between the second electrode 140 and the encapsulation layer 150.

A color filter CF may be provided over the encapsulation layer 150. The color filter CF may be provided over one surface of the second substrate 112 facing the first substrate 111. In this case, the first substrate 111 provided with the encapsulation layer 150 and the second substrate 112 provided with the color filter CF may be bonded to each other by a separate adhesive layer (not shown). The adhesive layer (not shown) may be an optically clear resin layer (OCR) or an optically clear adhesive film (OCA).

The color filter CF may be provided to be patterned for each of the subpixels SP1, SP2, SP3 and SP4. More specifically, the color filter CF may include a first color filter, a second color filter and a third color filter. The first color filter may be disposed to correspond to the light emission area EA1 of the first subpixel SP1, and may be a red color filter that transmits red light. The second color filter may be disposed to correspond to the light emission area EA2 of the second subpixel SP2, and may be a green color filter that transmits green light. The third color filter may be disposed to correspond to the light emission area EA3 of the third subpixel SP3, and may be a blue color filter that transmits blue light. In one aspect, the color filter CF may further include a fourth color filter. The fourth color filter may be disposed to correspond to the light emission area EA4 of the fourth subpixel SP4, and may be a white color filter that transmits white light. The white color filter may be formed of a transparent organic material that transmits white light.

A black matrix BM may be provided between the color filters CF and between the color filter CF and the transmissive area TA. The black matrix BM may be disposed between the subpixels SP1, SP2, SP3 and SP4 to prevent color mixture between adjacent subpixels SP1, SP2, SP3 and SP4 from occurring.

In addition, the black matrix BM may be disposed between the transmissive area TA and the plurality of subpixels SP1, SP2, SP3 and SP4 to prevent light emitted from each of the plurality of subpixels SP1, SP2, SP3 and SP4 from moving to the transmissive area TA.

The black matrix BM may include a material that absorbs light, for example, a black dye that absorbs all of the light in the visible wavelength range.

In the display panel 110 according to one aspect of the present disclosure, one first electrode 120 may be connected to the driving transistor TR through two connection portions CL1 and CL2. In the display panel 110 according to one aspect of the present disclosure, even though the bridge electrodes BE are disconnected from the divided electrode 125 in which the unintended particles P are located, the other divided electrodes 125 may stably be connected to the driving transistor TR through the first connection portion CL1 or the second connection portion CL2.

That is, in the display panel 110 according to one aspect of the present disclosure, only the area provided with the divided electrode 125b in which unintended particles P are located among the plurality of divided electrodes 125 becomes a dark spot, and light may normally be emitted in the area provided with the other divided electrodes 125. As a result, the display panel 110 according to one aspect of the present disclosure may reduce or minimize the size of the light emission area that becomes a dark spot when the unintended particles P are located.

In FIGS. 3 to 9, the first to fourth subpixels SP1, SP2, SP3 and SP4 provided in one pixel P are disposed around the middle area, but are not limited thereto. In another aspect, the first to fourth subpixels SP1, SP2, SP3 and SP4 provided in one pixel P may be disposed in a line in the first direction (e.g., X-axis direction) or the second direction (e.g., Y-axis direction).

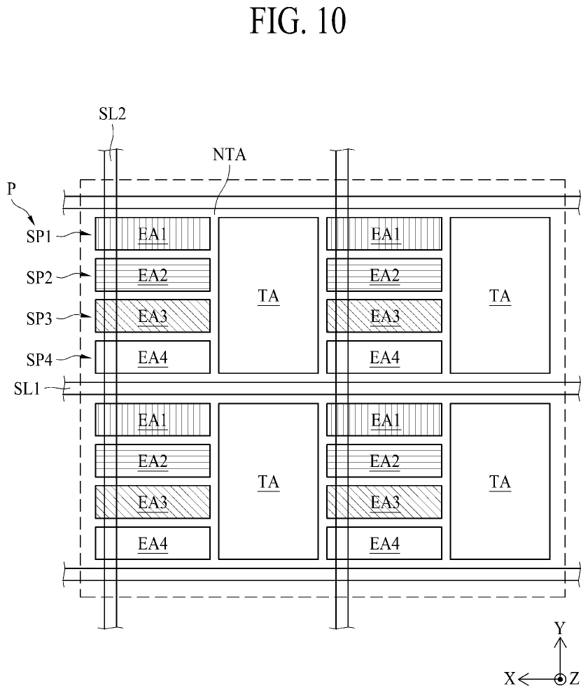

Hereinafter, an example in which the first electrode 120 is provided in a pixel structure, in which the first to fourth subpixels SP1, SP2, SP3 and SP4 are disposed in a line in the second direction (e.g., Y-axis direction), will be described with reference to FIGS. 10 to 12.

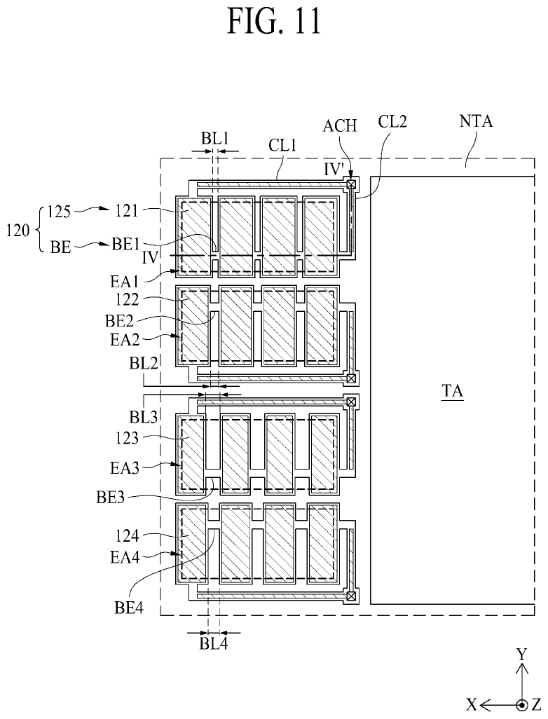

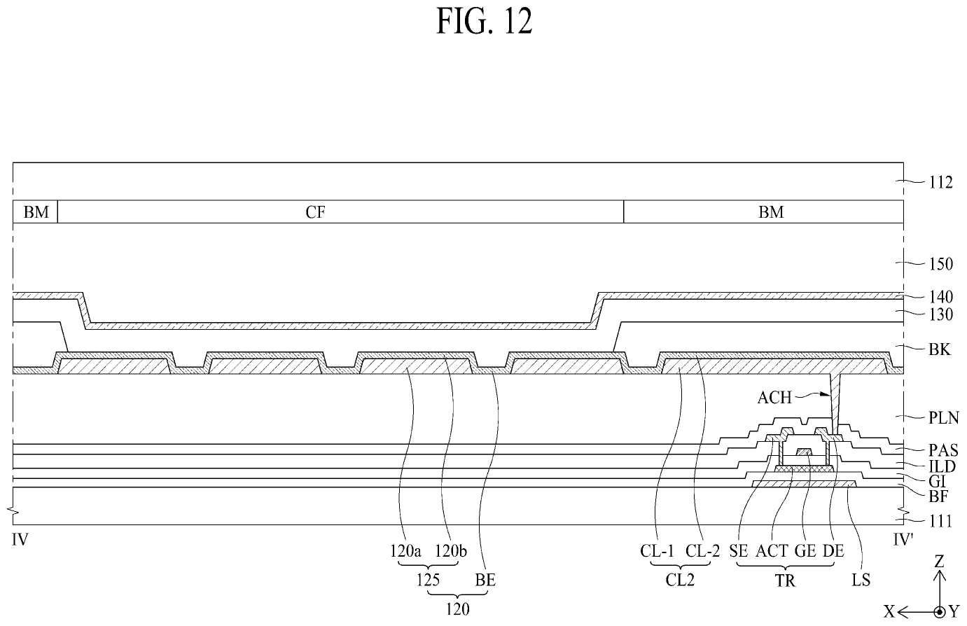

FIG. 10 is a view illustrating another example of a pixel provided in a display panel, FIG. 11 is a view illustrating a first electrode provided in the pixel shown in FIG. 10, and FIG. 12 is a cross-sectional view illustrating an example of line IV-IV′ of FIG. 10.

Referring to FIGS. 10 to 12, each of the pixels P is provided to overlap the first signal line SL1 or the second signal line SL2, and emits predetermined light to display an image. The light emission area EA may correspond to an area that emits light in the pixel P.

Each of the pixels P may include at least one of a first subpixel SP1, a second subpixel SP2, a third subpixel SP3 or a fourth subpixel SP4. The first subpixel SP1 may be provided to include a first light emission area EA1 emitting red light, the second subpixel SP2 may be provided to include a second light emission area EA2 emitting green light, the third subpixel SP3 may be provided to include a third light emission area EA3 emitting blue light, and the fourth subpixel SP4 may be provided to include a fourth light emission area EA4 emitting white light, but they are not limited thereto. Each of the pixels P may include a subpixel that emits light of a color other than red, green, blue and white. In addition, the arrangement order of the subpixels SP1, SP2, SP3 and SP4 may be changed in various ways.

Each of the plurality of pixels P may be provided in the non-transmissive area NTA disposed between transmissive areas TA. The plurality of pixels P may be disposed to be adjacent to each other in the non-transmissive area NTA in the second direction (e.g., Y-axis direction). The first subpixel SP1, the second subpixel SP2, the third subpixel SP3 and the fourth subpixel SP4, which are provided in each of the plurality of pixels P, may be disposed in a line in the second direction.

Each of the first subpixel SP1, the second subpixel SP2, the third subpixel SP3 and the fourth subpixel SP4, which are disposed as described above, may include a circuit element including a capacitor, a thin film transistor and the like, a plurality of signal lines for supplying a signal to the circuit element, and a light emitting element. The thin film transistor may include a switching transistor, a sensing transistor, and a driving transistor TR.

In the display panel 110, the plurality of signal lines as well as the first subpixel SP1, the second subpixel SP2, the third subpixel SP3 and the fourth subpixel SP4 should be disposed in the non-transmissive area NTA except the transmissive area TA. Therefore, the first subpixel SP1, the second subpixel SP2, the third subpixel SP3 and the fourth subpixel SP4 overlap at least one of the first signal line SL1 or the second signal line SL2.

Although FIG. 10 shows that the first subpixel SP1, the second subpixel SP2, the third subpixel SP3 and the fourth subpixel SP4 overlap at least a portion of the second signal line SL2 but do not overlap the first signal line SL1, the aspect of the present disclosure is not limited thereto. In another aspect, a portion of the first subpixel SP1, the second subpixel SP2, the third subpixel SP3 and the fourth subpixel SP4 may partially overlap the first signal line SL1. For example, a portion of the first subpixel SP1 adjacent to the first signal line SL1 may be adjacent to the first signal line SL1.

The plurality of signal lines may include a first signal line SL1 extended in the first direction (e.g., X-axis direction) and a second signal line SL2 extended in the second direction (e.g., Y-axis direction) as described above.

The first signal line SL1 may include a first scan line and a second scan line. The first scan line may supply a scan signal to the subpixels SP1, SP2, SP3 and SP4 of the pixel P disposed on a first side, for example, an upper side. The second scan line may supply a scan signal to the subpixels SP1, SP2, SP3 and SP4 of the pixel disposed on a second side, for example, a lower side.

The second signal line SL2 may include at least one data line, a pixel power line, a reference line and a common power line, but is not limited thereto.

Since the switching transistor, the sensing transistor, the driving transistor TR and the capacitor are substantially the same as those of the display panel 110 shown in FIGS. 3 to 9, their description will be omitted.

A passivation layer PAS may be provided over the circuit element including the switching transistor, the sensing transistor, the driving transistor TR and the capacitor and the plurality of signal lines supplying a signal to the circuit element. A planarization layer PLN for planarizing a step difference due to the driving transistor TR may be provided over the passivation layer PAS.

Light emitting elements comprised of a first electrode 120, an organic light emitting layer 130 and a second electrode 140, and a bank BK are provided over the planarization layer PLN.

The first electrode 120 may be provided for each of the subpixels SP1, SP2, SP3 and SP4 over the planarization layer PLN. More specifically, one first electrode 121 may be provided in the first subpixel SP1, another first electrode 120 may be provided in the second subpixel SP2, still another first electrode 120 may be provided in the third subpixel SP3, and further still another first electrode 120 may be provided in the fourth subpixel SP4. The first electrode 120 is not provided in the transmissive area TA.

The first electrode 120 provided in each of the plurality of subpixels SP1, SP2, SP3 and SP4 may include a plurality of divided electrodes 125 and at least one bridge electrode BE.

The plurality of divided electrodes 125 may include two or more, and may be disposed to be spaced apart from each other in the first direction (e.g., X-axis direction) or the second direction (e.g., Y-axis direction). For example, the plurality of divided electrodes 125 may include four as shown in FIGS. 10 and 11 and may be disposed to be spaced apart from one another in the second direction (e.g., Y-axis direction), but are not limited thereto. The plurality of divided electrodes 125 may include three, or may include five or more. Hereinafter, for convenience of description, the plurality of divided electrodes 125 include four.

Each of the plurality of divided electrodes 125 may include a first electrode layer 120a made of a first material and a second electrode layer 120b made of a second material as shown in FIG. 12.

The first material may include a metal material having high reflectance. For example, the first material may be, but is not limited to, molybdenum (Mo) or copper (Cu). The second material may include a transparent material. For example, the second material may be ITO, but is not limited thereto. The second material may be a material having higher resistance than the first material. Alternatively, the second material may be a material having a melting point lower than that of the first material.

The bridge electrode BE may be disposed between the plurality of divided electrodes 125 to connect the plurality of divided electrodes 125 with each other. More specifically, one bridge electrode BE may be disposed between two adjacent divided electrodes 125. At this time, the bridge electrodes BE may be provided in the same layer as the second electrode layer 120b of the divided electrodes 125.

One end of the bridge electrode BE may be connected to any one second electrode layer 120b of adjacent divided electrodes 125, and the other end thereof may be connected to the other second electrode layer 120b of the adjacent divided electrodes 125.

A width of a side of the bridge electrode BE, which is in contact with the divided electrodes 125, may be smaller than a width of a long side of the divided electrodes 125. Since the bridge electrode BE is provided to be thinner than the divided electrodes 125, resistance of the bridge electrode BE may be greater than that of the divided electrodes 125.

As described above, the first electrode 120, which includes the plurality of divided electrodes 125 and the bridge electrode BE, may be connected with the driving transistor TR through a connection portion CL.

In the display panel 110 according to one aspect of the present disclosure, one first electrode 120 may be connected to the driving transistor TR through two connection portions CL. More specifically, the connection portion CL may include a first connection portion CL1 and a second connection portion CL2, and each of the first connection portion CL1 and the second connection portion CL2 may be connected to the driving transistor TR through a contact hole ACH that passes through the planarization layer PLN and the passivation layer PAS.

In one aspect, the contact hole ACH may be provided among the subpixels SP1, SP2, SP3 and SP4 and between the subpixels SP1, SP2, SP3 and SP4 and the transmissive area as shown in FIG. 11. The first connection portion CL1 may be provided among the subpixels SP1, SP2, SP3 and SP4. The second connection portion CL2 may be provided between the subpixels SP1, SP2, SP3 and SP4 and the transmissive area TA.

One end of the first connection portion CL1 may be connected with a source electrode SE or a drain electrode of the driving transistor TR through the contact hole ACH. The other end of the first connection portion CL1 may be connected with any one of the plurality of divided electrodes 125 provided in the first electrode 120. At this time, the first connection portion CL1 may be connected to the divided electrode, which is disposed at the outermost portion on a first side, of the plurality of divided electrodes 125.

One end of the second connection portion CL2 may be connected with the source electrode SE or the drain electrode of the driving transistor TR through the contact hole ACH. In addition, the other end of the second connection portion CL2 may be connected to the other one of the plurality of divided electrodes 125 provided in the first electrode 120. At this time, the second connection portion CL2 may be connected to the divided electrode, which is disposed at the outermost portion on a second side, of the plurality of divided electrodes 125.

For example, four divided electrodes 125 may be disposed in a line in the second direction (e.g., Y-axis direction) as shown in FIG. 11. The bridge electrode BE may be disposed between adjacent divided electrodes 125. Therefore, the four divided electrodes 125 may electrically be connected to one another through the bridge electrode BE.

Meanwhile, one end of the first connection portion CL1 may be connected with the source electrode SE or the drain electrode DE of the driving transistor TR through the contact hole ACH, and the other end thereof may be connected with any one of the four divided electrodes 125. The first connection portion CL1 may be connected to the divided electrode, which is disposed at the outermost portion on a first side, of the four divided electrodes 125 disposed in a line.

One end of the second connection portion CL2 may be connected to the source electrode SE or the drain electrode DE of the driving transistor TR through the contact hole ACH, and the other end thereof may be connected with the other one of the four divided electrodes 125. The first connection portion CL1 may be connected to the divided electrode, which is disposed at the outermost portion on a second side, of the four divided electrodes 125 disposed in a line.

In the first electrode 120 comprised of four divided electrodes 125, one divided electrode disposed at the outmost portion on the first side may be connected with the driving transistor TR through the first connection portion CL1, and another divided electrode disposed at the outermost portion on the second side may be connected with the driving transistor TR through the second connection portion CL2.

As a result, the four divided electrodes 125 may be connected with the driving transistor TR through the first connection portion CL1, and may be connected with the driving transistor TR through the second connection portion CL2.

The first and second connection portions CL1 and CL2 described as above may be formed as a double layer as shown in FIG. 12. More specifically, the first connection portion CL1 and the second connection portion CL2 may include a first layer CL-1 and a second layer CL-2. The first layer CL-1 may be provided in the same layer as the first electrode layer 120a of the divided electrode 125, and may be spaced apart from the first electrode layer 120a of the divided electrode 125. The second layer CL-2 may be provided in the same layer as the second electrode layer 120b of the divided electrode 125, and may be extended from the second electrode layer 120b of the divided electrode 125.

The display panel 110 according to another aspect of the present disclosure is characterized in that the first electrode 120 comprised of a plurality of divided electrodes 125 and at least one bridge electrode BE is connected with the driving transistor TR through two connection portions CL1 and CL2. Therefore, in the display panel 110 according to another aspect of the present disclosure, even though unintended particles are located in a portion of the plurality of divided electrodes 125, only the corresponding divided electrode becomes a dark spot, and the other divided electrodes may normally operate.

More specifically, in the display panel 110 according to another aspect of the present disclosure, unintended particles P may be located in one of the plurality of divided electrodes 125. The divided electrode 125 in which the unintended particles P are located may generate a short with the second electrode 140. Therefore, the organic light emitting layer 130 provided over the divided electrode 125 in which the unintended particles P are located does not emit light.

In the display panel 110 according to another aspect of the present disclosure, the bridge electrodes BE connected to the divided electrode 125 in which unintended particles are located may be disconnected by Joule heating, whereby the divided electrode 125 in which unintended particles are located may electrically be separated from the other divided electrode 125 in which unintended particles do not are located.

In the display panel 110 according to another aspect of the present disclosure, the first electrode 120 may be connected with the driving transistor TR through two connection portions CL1 and CL2. Even though the bridge electrodes BE connected with the divided electrode 125 in which unintended particles P are located are disconnected, the other divided electrode 125 in which unintended particles P are not located may be connected with the driving transistor TR through the first connection portion CL1 or the second connection portion CL2.

That is, in the display panel 110 according to another aspect of the present disclosure, only the area provided with the divided electrode 125 in which unintended particles P are located among the plurality of divided electrodes 125 becomes a dark spot, and light may normally be emitted in the area provided with the other divided electrode 125. The display panel 110 according to another aspect of the present disclosure may reduce or minimize the size of the light emission area that becomes a dark spot when unintended particles P are located.

Meanwhile, the display panel 110 according to another aspect of the present disclosure may be designed such that the bridge electrodes BE provided in the first to fourth subpixels SP1, SP2, SP3 and SP4 have their respective lengths different from one another.

More specifically, the first electrode 120 provided in the first subpixel SP1 may include a plurality of first divided electrodes 121 and at least one first bridge electrode BE1. The first electrode 120 provided in the second subpixel SP2 may include a plurality of second divided electrodes 122 and at least one second bridge electrode BE2. The first electrode 120 provided in the third subpixel SP3 may include a plurality of third divided electrodes 123 and at least one third bridge electrode BE3. The first electrode 120 provided in the fourth subpixel SP4 may include a plurality of fourth divided electrodes 124 and at least one fourth bridge electrode BE4.

In the display panel 110 according to another aspect of the present disclosure, the first to fourth bridge electrodes BE1, BE2, BE3 and BE4 may be provided to have their respective lengths different from one another in consideration of the magnitude of the current supplied from the driving transistor TR.

A current required for each of the first to fourth subpixels SP1, SP2, SP3 and SP4 may be different depending on a color of light emitted from each of the first to fourth subpixels SP1, SP2, SP3 and SP4. A size of the driving transistor TR provided in each of the first to fourth subpixels SP1, SP2, SP3 and SP4 may be determined in consideration of the required current.

The first to fourth bridge electrodes BE1, BE2, BE3 and BE4 respectively provided in the first to fourth subpixels SP1, SP2, SP3 and SP4 may vary in resistance depending on the sizes of the driving transistors TR. When the size of the driving transistor TR is large, the current supplied from the driving transistor TR is large, whereby resistance of the bridge electrodes BE1, BE2, BE3 and BE4 may be large. On the other hand, when the size of the driving transistor TR is small, the current supplied from the driving transistor TR is small, whereby resistance of the bridge electrodes BE1, BE2, BE3 and BE4 may be small.

In the display panel 110 according to another aspect of the present disclosure, the length of the bridge electrodes BE1, BE2, BE3 and BE4 may be adjusted to adjust resistance of the current applied from the driving transistor TR to the bridge electrodes BE1, BE2, BE3 and BE4. Therefore, in the display panel 110 according to another aspect of the present disclosure, the first to fourth bridge electrodes BE1, BE2, BE3 and BE4 may have similar resistance.

For example, the driving transistor TR connected with the first electrode 120 of the first subpixel SP1 may be the largest, the driving transistor TR connected with the first electrode 120 of the second subpixel SP2 may be the second largest, the driving transistor TR connected with the first electrode 120 of the fourth subpixel SP4 may be the third largest, and the driving transistor TR connected with the first electrode 120 of the third subpixel SP3 may be the smallest.

In this case, a length BL1 of the first bridge electrode BE1 provided in the first subpixel SP1 may be shorter than a length BL2 of the second bridge electrode BE2 provided in the second subpixel SP2. The current applied to the first bridge electrode BE1 provided in the first subpixel SP1 may be greater than the current applied to the second bridge electrode BE2 provided in the second subpixel SP2. Therefore, the length BL1 of the first bridge electrode BE1 is shorter than the length BL2 of the second bridge electrode BE2, whereby a resistance difference between the first bridge electrode BE1 and the second bridge electrode BE2 may be reduced.

In addition, a length BL2 of the second bridge electrode BE2 provided in the second subpixel SP2 may be shorter than a length BL4 of the fourth bridge electrode BE4 provided in the fourth subpixel SP4. The current applied to the second bridge electrode BE2 provided in the second subpixel SP2 may be greater than the current applied to the fourth bridge electrode BE4 provided in the fourth subpixel SP4. Therefore, the length BL2 of the second bridge electrode BE2 is shorter than the length BL4 of the fourth bridge electrode BE4, whereby a resistance difference between the second bridge electrode BE2 and the fourth bridge electrode BE4 may be reduced.

A length BL4 of the fourth bridge electrode BE4 provided in the fourth subpixel SP4 may be shorter than a length BL3 of the third bridge electrode BE3 provided in the third subpixel SP3. The current applied to the fourth bridge electrode BE4 provided in the fourth subpixel SP4 may be greater than the current applied to the third bridge electrode BE3 provided in the third subpixel SP3. Therefore, the length BL4 of the fourth bridge electrode BE4 is shorter than the length BL3 of the third bridge electrode BE3, whereby a resistance difference between the third bridge electrode BE3 and the fourth bridge electrode BE4 may be reduced.

In the display panel 110 according to another aspect of the present disclosure as described above, when the current applied from the driving transistor TR is small, the length of the bridge electrode BE connected with the corresponding driving transistor TR may be increased, whereby resistance of the bridge electrode BE may be increased. Therefore, the display panel 110 according to another aspect of the present disclosure may make sure of disconnection of the bridge electrode BE when unintended particles are located on the divided electrode 125.

Meanwhile, in the display panel 110 according to another aspect of the present disclosure, the lengths of the bridge electrodes BE1, BE2, BE3 and BE4 are different from one another in each of the subpixels SP1, SP2, SP3 and SP4, whereby the sizes or the number of the divided electrodes 121, 122, 123 and 124 may be different from one another.

In one aspect, the divided electrodes 121, 122, 123 and 124 respectively provided in the subpixels SP1, SP2, SP3 and SP4 may be different from one another in width as shown in FIG. 11. More specifically, the divided electrodes 121, 122, 123 and 124 respectively provided in the subpixels SP1, SP2, SP3 and SP4 may have different widths in sides perpendicular to sides that are in contact with the bridge electrode BE1, BE2, BE3 and BE4, for example, short sides.

For example, the length BL1 of the first bridge electrode BE1 provided in the first subpixel SP1 may be longer than the length BL3 of the third bridge electrode BE3 provided in the third subpixel SP3. In this case, the first divided electrode 121 provided in the first subpixel SP1 may be wider than the third divided electrode 123 provided in the third subpixel SP3 in the width in the short side.

In another aspect, the divided electrodes 121, 122, 123 and 124 respectively provided in the subpixels SP1, SP2, SP3 and SP4 may be different from one another in number. For example, the length BL1 of the first bridge electrode BE1 provided in the first subpixel SP1 may be longer than the length BL3 of the third bridge electrode BE3 provided in the third subpixel SP3. In this case, the number of the first divided electrodes 121 provided in the first subpixel SP1 may be more than the number of the third divided electrodes 123 provided in the third subpixel SP3.

Since a bank BK, an organic light emitting layer 130, a second electrode 140, an encapsulation layer 150, a color filter CF and a black matrix BM are substantially the same as those shown in FIGS. 5 and 6, their detailed description will be omitted.

According to the present disclosure, the following advantageous effects may be obtained.

In the present disclosure, the first electrode includes a plurality of divided electrodes and a bridge electrode may be connected to the driving transistor through two connection portions. In the present disclosure, even though the bridge electrodes connected to the divided electrode in which unintended particles are located are disconnected, the other divided electrode may stably be connected with the driving transistor through one of the two connection portions. Therefore, the present disclosure can reduce or minimize the size of the light emission area that becomes a dark spot when unintended particles are located.

In addition, the present disclosure may adjust the length of the bridge electrode in accordance with the current applied from the driving transistor. Therefore, even though the current applied from the driving transistor is reduced, the bridge electrode may be disconnected when unintended particles are located on the divided electrode.

In addition, the bridge electrodes may be provided to have different lengths for each of the subpixels, so that the bridge electrodes respectively provided in the subpixels may have similar resistance.

It will be apparent to those skilled in the art that the present disclosure described above is not limited by the above-described aspects and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display device comprising:
a substrate provided with a display area for displaying an image by a plurality of subpixels;
a driving transistor provided over the substrate;
a first electrode provided in each of the plurality of subpixels over the driving transistor and including a plurality of divided electrodes and a bridge electrode connecting the plurality of divided electrodes;
a connection portion having one end connected to the driving transistor through a contact hole and another end connected to the first electrode;
a light emitting layer provided over the first electrode; and
a second electrode provided over the light emitting layer.

2. The display device of claim 1, wherein the connection portion includes a first connection portion connected with one of the plurality of divided electrodes and a second connection portion connected with another one of the plurality of divided electrodes, and
wherein the first and second connection portions are connected through the contact hole.

3. The display device of claim 2, wherein the first connection portion is connected to one of the plurality of divided electrodes, which is disposed at an outermost portion on a first side, and the second connection portion is connected to another one of the plurality of divided electrodes, which is disposed at an outermost portion on a second side.

4. The display device of claim 1, wherein the first electrode includes a first electrode layer made of a first material and a second electrode layer provided over the first electrode layer and made of a second material.

5. The display device of claim 4, wherein the plurality of divided electrodes are spaced apart from each other, and each of the plurality of divided electrodes includes the first electrode layer and the second electrode layer.

6. The display device of claim 5, wherein the bridge electrode is disposed between two adjacent divided electrodes, and has one end connected to the second electrode layer of one of the two adjacent divided electrodes and another end connected to the second electrode layer of another one of the two adjacent divided electrodes.

7. The display device of claim 4, wherein the bridge electrode is formed of a same material as the second electrode layer and is connected to the second electrode layer of each of the two adjacent divided electrodes.

8. The display device of claim 7, wherein the bridge electrode has a first width, which is in contact with the divided electrodes, narrower than a second width of the plurality of divided electrodes.

9. The display device of claim 4, wherein the first material includes a reflective material, and the second material includes a transparent material.

10. The display device of claim 4, wherein the second material has a higher resistance or a lower melting point than the first material.

11. The display device of claim 1, wherein the bridge electrode connected with one of the plurality of divided electrodes where unintended particles are located is disconnected by Joule heating.

12. The display device of claim 1, wherein the plurality of subpixels include a first subpixel emitting light of a first color and a second subpixel emitting light of a second color,
the first electrode provided in the first subpixel includes a plurality of first divided electrodes and a first bridge electrode connecting the plurality of first divided electrodes, and
the first electrode provided in the second subpixel includes a plurality of second divided electrodes and a second bridge electrode connecting the plurality of second divided electrodes.

13. The display device of claim 12, wherein the first bridge electrode and the second bridge electrode have lengths different from each other.

14. The display device of claim 12, wherein the driving transistor includes a first driving transistor connected with the first electrode provided in the first subpixel and a second driving transistor connected to the first electrode provided in the second subpixel, and
wherein the first driving transistor and the second driving transistor have sizes different from each other.

15. The display device of claim 12, wherein the first driving transistor is larger than the second driving transistor, and the first bridge electrode is shorter than the second bridge electrode.

16. The display device of claim 12, wherein the first and second divided electrodes are different from each other in a width of a side perpendicular to the side that is in contact with the bridge electrode.

17. The display device of claim 16, wherein the first bridge electrode has a length shorter than the second bridge electrode, and the first divided electrode has a width greater than the second divided electrode.

18. The display device of claim 1, wherein the plurality of subpixels include a red subpixel and a blue subpixel, and a bridge electrode of the red subpixel has a length shorter than a bridge electrode of the blue subpixel.

19. A display device comprising:
a substrate provided with transmissive areas and a plurality of subpixels disposed between the transmissive areas;
a first electrode provided in each of the plurality of subpixels over the substrate, and including a plurality of divided electrodes and a bridge electrode disposed between two adjacent divided electrodes to connect the plurality of divided electrodes;
a light emitting layer provided over the first electrode; and
a second electrode disposed over the light emitting layer.

20. The display device of claim 19, further comprising:
a driving transistor provided between the substrate and the first electrode;
a first connection portion of which one end is connected to the driving transistor through a contact hole and another end is connected to one of the plurality of divided electrodes; and
a second connection portion of which one end is connected to the driving transistor through the contact hole and another end is connected to another one of the plurality of divided electrodes.

21. The display device of claim 20, further comprising a bank provided over the first connection portion, the second connection portion and the contact hole.

22. The display device of claim 20, wherein the first connection portion is provided between the plurality of subpixels, and the second connection portion is provided over the transmissive area and the plurality of subpixels.

23. The display device of claim 19, wherein the first electrode includes a first electrode layer made of a reflective material, and a second electrode layer provided over the first electrode layer and made of a transparent material.

24. The display device of claim 23, wherein the plurality of divided electrodes are spaced apart from one another, each of the plurality of divided electrodes including the first electrode layer and the second electrode layer, and
wherein the bridge electrode is formed of a same material as the second electrode layer, and is connected to a second electrode layer of each of the two adjacent divided electrodes.

25. The display device of claim 19, wherein the plurality of subpixels include a first subpixel emitting light of a first color and a second subpixel emitting light of a second color,
wherein the first electrode provided in the first subpixel includes a plurality of first divided electrodes and a first bridge electrode connecting the plurality of first divided electrodes, and
wherein the first electrode provided in the second subpixel includes a plurality of second divided electrodes and a second bridge electrode connecting the plurality of second divided electrodes.

26. The display device of claim 25, wherein the first bridge electrode and the second bridge electrode have lengths different from each other.

27. The display device of claim 26, further comprising:
a first driving transistor connected with the first electrode provided in the first subpixel; and
a second driving transistor connected to the first electrode provided in the second subpixel,
wherein the first driving transistor has a size larger than the second driving transistor, and the first bridge electrode has a length shorter than the second bridge electrode.

28. The display device of claim 19, wherein the plurality of subpixels include a red subpixel, a green subpixel, a blue subpixel, and a white subpixel,
wherein the bridge electrode of the red subpixel has a length shorter than the bridge electrode of each of the green subpixel, the blue subpixel and the white subpixel, and
wherein the bridge electrode of the blue subpixel has a length longer than the bridge electrode of each of the red subpixel, the green subpixel and the white subpixel.

29. The display device of claim 28, wherein the bridge electrode of the green subpixel has a length shorter than the bridge electrode of the white subpixel.

30. A display device comprising:
a plurality of subpixels displaying an image;
a driving transistor driving the plurality of subpixels;
an anode electrode disposed in the plurality of subpixels and including first, second and third anode electrode layers adjacent with one another;
a first bridge electrode electrically connecting one of two adjacent anode electrode layers with each other;
a second bridge electrode electrically connecting another one of two adjacent anode electrode layers with each other;
a first connection portion having one end connected to the driving transistor through a contact hole and another end connected to an outermost one of the first, second and third anode electrode layers; and
a second connection portion having one end connected to the driving transistor through a contact hole and another end connected to another outermost one of the first, second and third anode electrode layers.

31. The display device of claim 30, further comprising:
a light emitting layer disposed on the anode electrode; and
a cathode electrode disposed on the light emitting layer.

32. The display device of claim 30, wherein at least one of the first and second bridge electrodes connected with two adjacent anode electrode layers where unintended particles are located is disconnected by Joule heating.
